(19) United States
(12) Patent Application Publication
(10) Pub. No.: US 2008/0053519 A1
(43) Pub. Date: Mar. 6, 2008

(54) Laminated photovoltaic cell

(75) Inventors: David Pearce, Saratoga, CA (US); Dennis Hollars, San Jose, CA (US)

Correspondence Address: FOLEY AND LARDNER LLP;SUITE 500, 3000 K STREET NW, WASHINGTON, DC, 20007, US

(73) Assignee: Miasole

(21) Appl. No.: 11/512,415

(22) Filed: Aug. 30, 2006

(51) Int. Cl. H01L 31/00

(52) U.S. Cl. 136/252

(57) ABSTRACT

The invention provides a thin flexible photovoltaic cell for building integrated photovoltaic (BIPV) applications. The photovoltaic cell is deposited on a thin metallic substrate and is integrated with residential structures. These residential structures may be roofing slates, roofing tiles, building claddings and the like. An arrangement of conducting layers is described for increasing the conversion efficiency of the photovoltaic cell. The arrangement of the conducting layers result in high current collection. The photovoltaic cell is encapsulated by encapsulating layers, wherein the encapsulating layers are made of chemically inert and ultraviolet ray resistant polymers.

### BACKGROUND

The present invention relates to the field of photovoltaics. More specifically, the present invention relates to the construction of a flexible thin film photovoltaic cell and its integration with building or roofing products.

Photovoltaic cells are widely used in residential structures and roofing materials for generation of electricity. A plurality of photovoltaic cells are interconnected in series or in parallel and are integrated with residential structures such as roofing slates, roofing tiles, building claddings and the like. The photovoltaic cells integrated with residential structures are deposited on a substrate, such as a stainless steel substrate.

Existing photovoltaic cells are deposited on a relatively thick and heavy stainless substrate, making them difficult to integrate with the residential structures. Further, the elements of the photovoltaic cell produce corrosive elements on reaction with moisture which reduce the life of the photovoltaic cell. Also, in photovoltaic cells used at present, a conductive grid line layer is deposited on a top transparent electrode layer. In these photovoltaic cells, a less than perfect ohmic contact is made between the conductive grid line layer and the top transparent electrode layer of the photovoltaic cell, due to which the photovoltaic cells have low conversion efficiency for converting sunlight to electricity.

Various transparent encapsulants, such as organic polymers, are used for encapsulating the photovoltaic cell to prevent the incursion of moisture into the photovoltaic cell. A copolymer of ethylene and vinyl acetate (ethylene vinyl acetate (EVA)) is a commonly used polymeric material for encapsulating the photovoltaic cells. For manufacturing EVA, an organic peroxide is added to cross-link vinyl acetate. However, the organic peroxide used in this process is not completely consumed during the manufacturing process. The remaining organic peroxide causes degradation of EVA. Further, lamination of photovoltaic cell with EVA is carried out in vacuum because oxygen reduces the cross-linking of EVA. The imperfect cross-linking of EVA results in the formation of a less compact laminating layer. Further, EVA produces acetic acid when it comes in contact with water. The acetic acid attacks and corrodes the transparent and conducting electrode layer of the photovoltaic cell.

Accordingly, there is a need for a photovoltaic cell that is thin and flexible which should be able to easily integrate with the residential structures. Further, the photovoltaic cell should have higher conversion efficiency for converting trapped solar energy to electricity. The photovoltaic cell should have adequate protection from moisture and environmental conditions.

### SUMMARY

One embodiment of the invention provides a photovoltaic cell, comprising a back electrode layer, a semiconductor p-n junction located over the back electrode layer, a conductive grid line layer located over the semiconductor p-n junction, and a first top transparent electrode layer located over the conductive grid line layer. The conductive grid line layer is located between the first top transparent electrode layer and the semiconductor p-n junction.

### BRIEF DESCRIPTION OF THE DRAWINGS

The preferred embodiments of the invention will hereinafter be described in conjunction with the appended drawings provided to illustrate and not to limit the invention, wherein like designations denote like elements, and in which:

FIG. 1 is a block diagram showing an exemplary environment in which the present invention may be practiced;

FIG. 2a is a cross-section of a photovoltaic cell representing an arrangement of a top transparent electrode layer and a conductive grid line layer, in accordance with an embodiment of the present invention;

FIG. 2b is a cross-section of a photovoltaic cell representing an arrangement of the top transparent electrode layer and the conductive grid line layer, in accordance with another embodiment of the present invention;

FIG. 3 is a cross-section of a photovoltaic cell representing an arrangement of a barrier layer with respect to the top transparent conducting layer, in accordance with various embodiments of the present invention;

FIG. 4 is a cross-section of a photovoltaic cell representing an arrangement of a sealing layer, in accordance with various embodiments of the present invention; and

FIG. 5 is a cross-section of a photovoltaic cell representing an arrangement of a sealing layer and a laminating layer, in accordance with various embodiments of the present invention.

### DESCRIPTION OF THE EMBODIMENTS

The embodiments of the present invention provide a photovoltaic cell that is deposited on a thin stainless steel substrate. The ohmic contact between a top transparent electrode layer and a conductive grid line layer of the photovoltaic cell is provided from the top surface of the conductive grid line layer. Further, the photovoltaic cell is encapsulated in one or more chemically inert polymer layers.

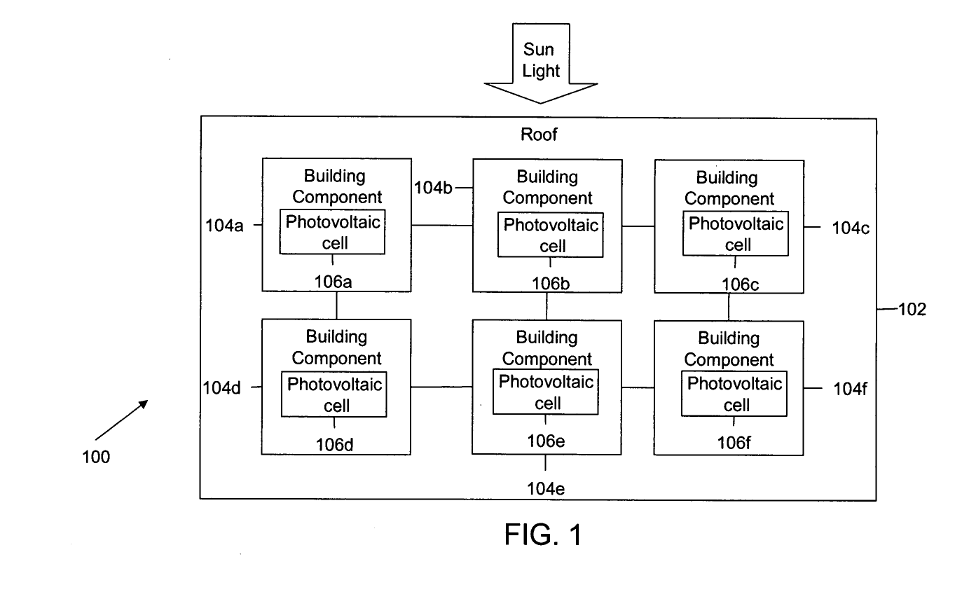

FIG. 1 is a block diagram showing an exemplary environment 100 in which the present invention may be practiced. Environment 100 includes a roof 102, a plurality of building components 104a, 104b, 104c, 104d, 104e, and 104f, and a plurality of photovoltaic cells 106a, 106b, 106c, 106d, 106e, and 106f. Building components 104a, 104b, 104c, 104d, 104e and 104f are, hereinafter, referred to as building components 104. Photovoltaic cells 106a, 106b, 106c, 106d, 106e and 106f are, hereinafter, referred to as photovoltaic cells 106.

Photovoltaic cells 106 are placed on/or attached to building components 104. In various embodiments of the invention, the building components 104 may be roofing slates, roofing tiles, building claddings and the like. Photovoltaic cells 106 are interconnected in series or in parallel for the generation of electricity.

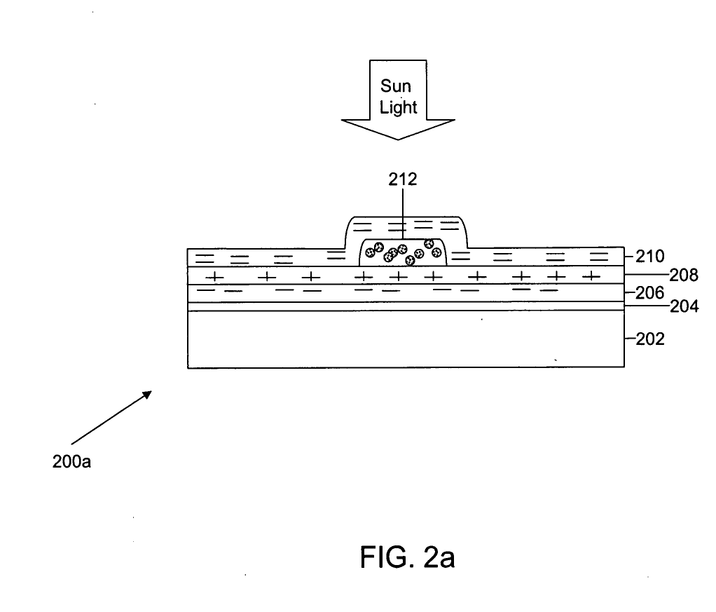

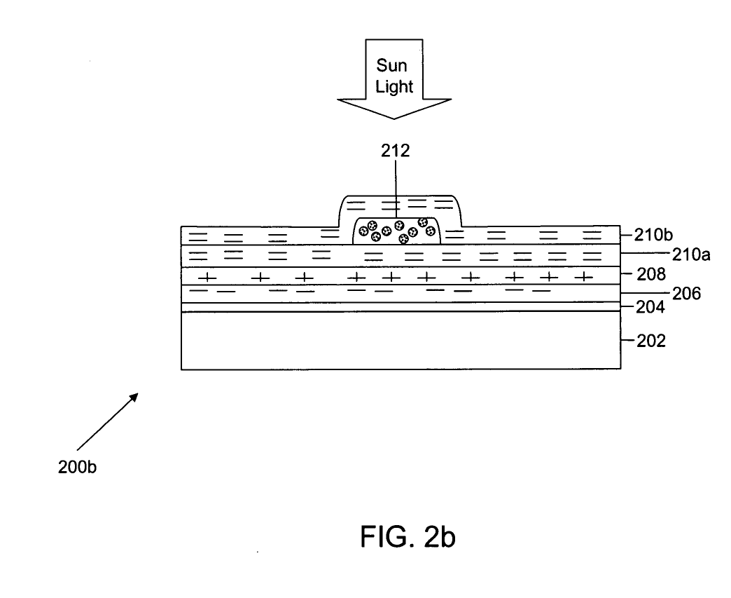

FIG. 2a is a cross-section of a photovoltaic cell 106 representing an arrangement 200a of a top transparent electrode layer and a conductive grid line layer, in accordance with an embodiment of the present invention. FIG. 2a includes a substrate 202, a back electrical contact layer 204, a p-type semiconductor layer 206, an n-type semiconductor layer 208, a top transparent electrode layer 210 and a conductive grid line layer 212.

Substrate 202 is preferably made of thin metallic stainless steel. In various alternative embodiments of the present invention, substrate 202 may be made of other metals capable of sustaining high temperatures. Examples of substrate 202 include, but are not limited to, titanium, copper, aluminum, beryllium and the like. In various embodiments of the invention, the substrate 202 is relatively thin, such as for example, less than or equal to about 2 mils, thereby making photovoltaic cell 106 light in weight. However, other suitable thicknesses may also be used. Light weight photovoltaic cell 106 is easy to integrate with residential structures 104. The conductive substrate 202 can act as a bottom electrode of the cell 106.

Back electrical contact layer 204 is deposited on substrate 202. Back electrical contact layer 204 covers the entire back surface of photovoltaic cell 106 and provides electrical contact to allow electrical current to flow through photovoltaic cell 106. P-type semiconductor layer 206 is deposited on back electrical contact layer 204. N-type semiconductor layer 208 is deposited on p-type semiconductor layer 206 to complete a p-n junction. Any suitable semiconductor materials, such as CIGS, CIS, CdTe, CdS, ZnS, ZnO, amorphous silicon, polycrystalline silicon, etc. may be used for layers 206, 208. For example, the p-type semiconductor layer 206 may comprise CIGS or CIS, and the n-type semiconductor layer 208 may comprise CdS or a cadmium free material, such as ZnS, ZnO, etc. Top transparent electrode layer 210 is deposited on the p-n junction.

Top transparent electrode layer 210 is preferably a layer of conducting oxides such as ITO, and is deposited for current collection and light enhancement. Conductive grid line layer 212 provides a low resistance path for electrons to flow through the electrical contact layers. The conductive grid line layer 212 is made of highly conductive metal or its alloys such as nickel, copper, silver and the like. Since these materials are not transparent, the layer is shaped as a grid of lines, thus exposing the semiconductor layer 208 to sunlight through openings in the grid. In an embodiment of the present invention, the top transparent electrode layer 210 is deposited over conductive grid line layer 212. The conductive grid line layer 212 is deposited over a section of photovoltaic cell 106, thus providing a larger surface area for absorbing the sun-light. Arrangement 200a provides a good ohmic contact between the top surface of conductive grid line layer 212 and top transparent electrode layer 210.

FIG. 2b is a cross-section of a photovoltaic cell 106 representing an arrangement 200b of top transparent electrode layer 210 and conductive grid line layer 212, in accordance with another embodiment of the present invention. The arrangement 200b of FIG. 2b includes substrate 202, back electrical contact layer 204, p-type semiconductor layer 206, n-type semiconductor layer 208, a first top transparent electrode layer 210a, a second top transparent electrode layer 210b and conductive grid line layer 212. Layer 212 is located between layers 210a and 210b.

In this embodiment of the present invention, the first top transparent electrode layer 210a is deposited on the n-type semiconductor layer 208. Further, the conductive grid line layer 212 is deposited on the transparent electrode layer 210a and thereafter, the second top transparent electrode layer 210b is deposited on conductive grid line layer 212. The dual top transparent electrode layer arrangement mentioned above provides an increased ohmic contact between the conductive grid line layer 212 and the sublayers 210a and 210b of top transparent electrode layer 210.

In one embodiment of the invention, the conductive grid line layer 212 may be deposited by screen printing, pad printing, ink jet printing and the like. The ohmic contact between conductive grid line layer 212 and top transparent electrode layer 210 increases further when conductive grid line layer 212 is made of printed conductive inks. This is because the polymer carrier liquid of the ink slumps during the curing, leaving the conducting metallic particles at the top of conductive grid line layer 212. Since the conducting metallic particles are exposed at the top of conductive grid line layer 212, the top transparent electrode layer 210b achieves increased ohmic contact with conductive grid line layer 212 from the top surface of conductive grid line layer 212. Moreover, the dual top transparent electrode layer arrangement further provides additional corrosion protection for conductive grid line layer 212.

In another embodiment of the present invention, conductive grid line layer 212 is deposited by vacuum metal deposition or electroless plating. In case of the plating process, a predetermined seed pattern of grid lines is printed and metallic lines are then built on the pattern in the plating bath as in the case of printed circuit boards. A two-step plating process is followed to deposit conductive grid line layer 212. In the first step, a thin metal seed film, such as nickel, is deposited on the underlying transparent conductor. In the second step, the remaining portion of the grid line pattern is plated with highly conductive metals, such as copper, silver and the like.

Top transparent electrode layers 210a and 210b are preferably made of transparent conducting oxide (TCOs). The TCOs are non-stoichiometric metal oxides and are very sensitive to oxidation to complete their stoichiometry. Small deviations from stoichiometry make the TCOs electrically conductive. If exposed to water-vapor for a long duration, the TCOs undergo oxidation and become stoichiometric. This results in a decrease in the conductivity of the TCOs, and as a result, the conversion efficiency of photovoltaic cell 106 decreases. Therefore, protection of top transparent electrode layer 210 from the water-vapor is desirable for high conversion efficiency of the photovoltaic cell 106. The TCOs have optical index of about 2. In various embodiments of the present invention, the TCOs may be aluminum zinc oxide (AZO), indium tin oxide (ITO), or cadmium tin oxide.

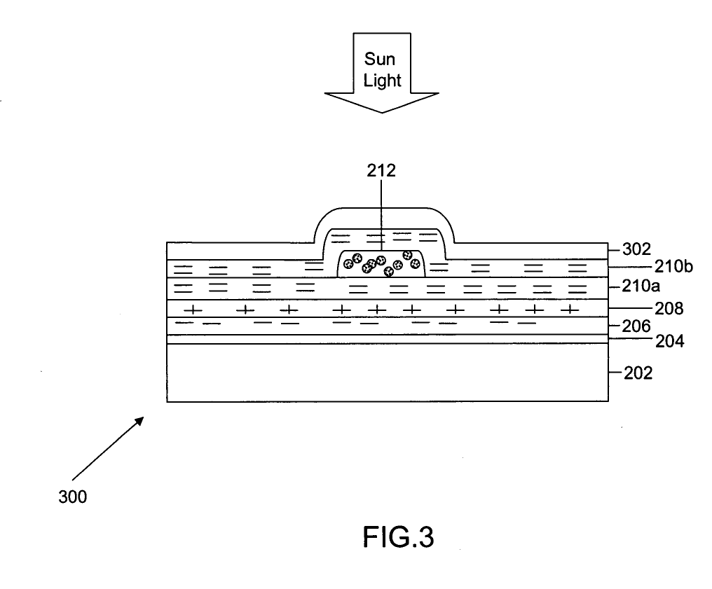

FIG. 3 is a cross-section of a photovoltaic cell 106 representing an arrangement 300 of a barrier layer 302 arranged over the top transparent conducting layer 210, in accordance with another embodiment of the present invention. Arrangement 300 of FIG. 3 includes substrate 202, back electrical contact layer 204, p-type semiconductor layer 206, n-type semiconductor layer 208, top transparent electrode layer 210a, top transparent electrode layer 210b, conductive grid line layer 212 and barrier layer 302. While both layers 210a, 210b are shown in FIG. 3, only a single TCO layer 210 may be formed above or below layer 212.

Barrier layer 302 is deposited on top transparent electrode layer 210 to protect top transparent electrode layer 210 from moisture and water vapors. In various embodiment of the invention, barrier layer 302 is deposited by sputtering. Sputtering is a low temperature method for depositing barrier layer 302, which does not result in overheating of the photovoltaic cell 106 underneath. Preferably, layer 302 comprises one or more films of inorganic materials.

In one embodiment of the present invention, barrier layer 302 is made of material with optical index between 1.2 and 2.0. The optical property of barrier layer 302 is important for reducing reflection losses. An optical index in the range of 1 to 2 avoids significant reflection losses. In an embodiment of the invention, barrier layer 302 may be made of amorphous silicon dioxide (such as silica, SiO₂) or crystalline quartz. In another embodiment of the invention, barrier layer 302 may be made from various mixtures of amorphous or crystalline silicon dioxide and aluminum oxide (such as alumina or sapphire). The optical index of sputtered silicon dioxide is 1.48, while the optical index of aluminum oxide (sapphire) is 1.8. Therefore, the mixture of sputtered silicon dioxide and aluminum oxide possesses intermediate optical index which does not cause significant reflection losses and also provides barrier properties to protect underlying TCOs.

In another embodiment of the present invention, barrier layer 302 may be made of alternating thin films of silicon oxide and aluminum oxide to optimize the water-vapor barrier properties. The alternating thin layers of silicon oxide and aluminum oxide may be made by using the dual rotary magnetron sputtering technology using dual sputtering targets at high deposition rates. Barrier layer 302 deposited by the method mentioned above includes optical properties, which do not cause significant reflection losses and provide environmental protection to top transparent electrode layer 210. If desired, an organic encapsulation layer, such as EVA, is deposited over layer 302.

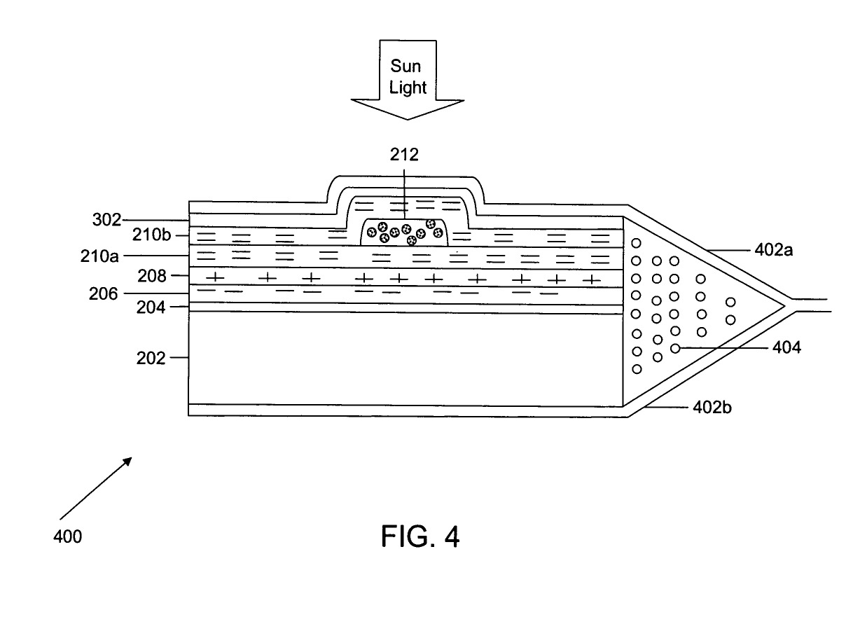

FIG. 4 is a cross-section of a photovoltaic cell representing an arrangement 400 of a sealing layer, in accordance with another embodiment of the present invention. The arrangement of FIG. 4 includes substrate 202, back electrical contact layer 204, p-type semiconductor layer 206, n-type semiconductor layer 208, top transparent electrode layer 210a, top transparent electrode layer 210b, conductive grid line layer 212, barrier layer 302, a first sealing layer 402a, a second sealing layer 402b, and an adhesive element 404. If desired layer 302 may be omitted and separate layers 210a and 210b may be substituted with a single layer 210.

Sealing layers 402a and 402b are deposited to provide an initial seal to the photovoltaic cell 106. Since the photovoltaic cell 106 is very thin, sealing layers 402a and 402b may be significantly thinner than in the prior art since there is less thickness to cover. In various embodiments of the invention, sealing layers 402a and 402b are deposited by a faster and more economical non-vacuum hot-nip roller process. In an embodiment of the present invention, sealing layers 402a and 402b may be made of organic material such as silicones and/or acrylics. In another embodiment of the present invention, laminating layers 402a and 402b may be made of inorganic material, such as glass.

Adhesive element 404 is embedded between sealing layers 402a and 402b. Adhesive element 404 provides a secondary seal to the photovoltaic cell 106 and prevents moisture incursion through and along edges of sealing layers 402a and 402b. In an embodiment of the present invention, adhesive element 404 may be made of Room Temperature Vulcanized Silicones (RTV silicones). In another embodiment of the present invention, adhesive element 404 may be made of polyisobutylene rubber (butyl rubber).

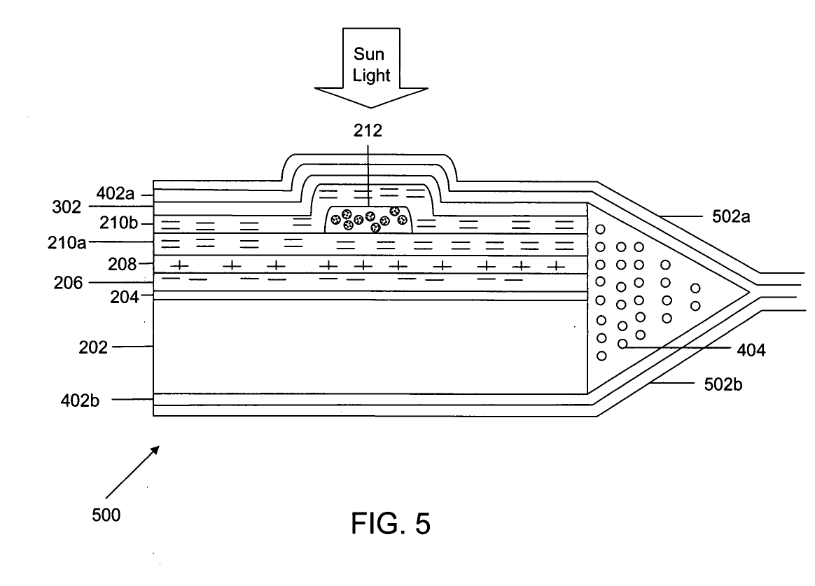

FIG. 5 is a cross-section of a photovoltaic cell representing an arrangement 500 of sealing layer 402 and laminating layer, in accordance with another embodiment of the present invention. The arrangement 500 of FIG. 5 includes substrate 202, back electrical contact layer 204, p-type semiconductor layer 206, n-type semiconductor layer 208, top transparent electrode layer 210a, top transparent electrode layer 210b, conductive grid line layer 212, barrier layer 302, sealing layer 402a, sealing layer 402b, adhesive element 404, a first laminating layer 502a, and a second laminating layer 502b. Layer 302 may be omitted and a single layer 210 used instead of layers 210a and 210b.

Laminating layers 502a and 502b laminate the photovoltaic cell 106 and provide ultra-violet resistance, chemical-resistance and weather-resistance to the photovoltaic cell 106. Laminating layer 502b readily bonds with laminating layer 502a. The top laminating layer 502a is made of inert fluropolymers. In an embodiment of the present invention, laminating layer 502a is made of Ethylene Tetrafluoro Ethylene polymer (ETFE). The ETFE is available in the market under the trade name Tefzel.

In one embodiment of the invention, the bottom laminating layer 502b is made of a chemically inert polymers such as polyvinyl fluoride (tedlar), high density and/or filled Polyethylene Terephthalate (PET), and the like. In another embodiment of the present invention, the laminating layer 502b may be made of a thin metal foil. In another embodiment of the present invention, the laminating layer 502b may be made of glass or some other opaque material. In the case of roofing applications, laminating layer 502b may be a roofing membrane. Thus, the material of layer 502a is preferably different from the material of claim 502b.

Sealing layers 402a, 402b and laminating layers 502a, 502b are extended and molded as shown in FIG. 5. The arrangement of sealing layer 402 and laminating layer 502 given above provides increased protection to the photovoltaic cell 106 from moisture and water vapor. Adhesive element 404 is not electrically conductive and also provides sealing around the edges of an entire string of the photovoltaic cells 106 that have been electrically joined together.

The photovoltaic cell of the embodiments of the present invention provides many advantages. The thin, flexible photovoltaic cell may be used for building integrated photovoltaic (BIPV) applications. The photovoltaic cell of the embodiments present invention is deposited on a thin metallic substrate of stainless steel which is light in weight. The photovoltaic cell provides increased ohmic contact between the conductive grid line layer and the top transparent electrode layer, thereby resulting in an increase in the conversion efficiency of the photovoltaic cell.

Further, the photovoltaic cell provides increased protection against the moisture and environmental conditions. The transparent conducting oxides are protected from moisture by depositing a barrier layer of silicon and/or aluminum oxide layer. The photovoltaic cell may include encapsulating and/or laminating layers with specific optical properties which prevents the reflection losses. The photovoltaic cell prevents moisture incursion even along the edges of the photovoltaic cell by embedding an adhesive element between the sealing layers. Further, the materials used in forming the encapsulating and laminating layers of the photovoltaic cell are chemically inert and stable under environmental conditions.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

What is claimed is:

1. A photovoltaic cell, comprising:
a back electrode layer located over a substrate;
a semiconductor p-n junction located over the back electrode layer;
a conductive grid line layer located over the semiconductor p-n junction; and
a first top transparent electrode layer located over the conductive grid line layer, such that the conductive grid line layer is located between the first top transparent electrode layer and the semiconductor p-n junction.

2. The photovoltaic cell of claim 1, wherein an ohmic contact is made between a top surface of the conductive grid line layer and a bottom surface of the top transparent electrode layer.

3. The photovoltaic cell of claim 1, wherein the substrate comprises a thin, flexible stainless steel substrate and the semiconductor p-n junction comprises a CIGS—CdS p-n junction.

4. The photovoltaic cell of claim 1, wherein the top transparent electrode layer is made of a transparent conducting oxide and the conductive grid line layer is made of a non-transparent metal or metal alloy.

5. The photovoltaic cell of claim 1, further comprising a second top transparent electrode layer located between the conductive grid line layer and the semiconductor p-n junction, such that the conductive grid line layer is located between the first and the second top transparent electrode layers.

6. The photovoltaic cell of claim 1, further comprising a transparent barrier layer located over the first top transparent electrode layer, wherein the barrier layer is adapted to prevent moisture incursion into the cell.

7. The photovoltaic cell of claim 1, further comprising at least one of a sealing layer and a laminating layer.

8. A photovoltaic cell, comprising:
a back electrode layer located over a substrate;
a semiconductor p-n junction located over the back electrode layer;
a conductive grid line layer located over the semiconductor p-n junction;
a top transparent electrode layer located over the semiconductor p-n junction; and
a sputtered, inorganic barrier layer having an optical index between 1.2 and 2.0 located over the top transparent electrode layer.

9. The photovoltaic cell of claim 8, wherein the barrier layer comprises at least one of silicon oxide and aluminum oxide.

10. The photovoltaic cell of claim 9, wherein the barrier layer comprises a mixture of silicon oxide and aluminum oxide.

11. The photovoltaic cell of claim 9, wherein the barrier layer comprises alternating sublayers of silicon oxide and aluminum oxide.

12. The photovoltaic cell of claim 11, wherein the barrier layer is deposited by a dual rotary magnetron sputtering method.

13. A photovoltaic cell, comprising:
a back electrode layer located over a substrate;
a semiconductor p-n junction located over the back electrode layer;
a conductive grid line layer located over the semiconductor p-n junction;
a top transparent electrode layer located over the semiconductor p-n junction;
a first inert fluoropolymer laminating layer located over the top transparent electrode; and
a second laminating layer of a material different than the first laminating layer located below the substrate.

14. The photovoltaic cell of claim 13, wherein the second laminating layer comprises an inert polymer, a metal foil, glass or a roofing membrane material.

15. The photovoltaic cell of claim 13, further comprising:
a first sealing layer located between the top transparent electrode layer and the first laminating layer; and
a second sealing layer located between the substrate and the second laminating layer.

16. The photovoltaic cell of claim 15, wherein edges of the first and the second sealing layers are sealed by an adhesive material.

17. The photovoltaic cell of claim 15, further comprising an inorganic, transparent barrier layer located between the top transparent electrode layer and the first sealing layer.

18. A method of making a photovoltaic cell, comprising:
forming a back electrode layer over a substrate;
forming a semiconductor p-n junction over the back electrode layer;
forming a conductive grid line layer over the semiconductor p-n junction;
forming a top transparent electrode layer over the semiconductor p-n junction; and
forming a first sealing layer over the top transparent electrode and a second sealing layer below the substrate by a hot-nip roller sealing process.

19. The method of claim 18, further comprising sealing edges of the first and the second sealing layers by an adhesive material

20. The method of claim 18, further comprising sputtering a transparent inorganic barrier layer over the top transparent electrode layer prior to forming the first sealing layer.
